(19) United States
(12) Patent Application Publication
(10) Pub. No.: US 2026/0205227 A1
(43) Pub. Date: Jul. 16, 2026

(54) LOW DENSITY PARITY CHECK TECHNIQUES IN WIRELESS COMMUNICATIONS

(71) Applicant: QUALCOMM Incorporated, San Diego, CA (US)

(72) Inventors: Pinar SEN, San Diego, CA (US); Wei YANG, San Diego, CA (US); Jing JIANG, San Diego, CA (US)

(21) Appl. No.: 19/367,616

(22) Filed: Oct. 23, 2025

Related U.S. Application Data
(60) Provisional application No. 63/746,089, filed on Jan. 16, 2025.

(51) Int. Cl. H04L 1/00

(52) U.S. Cl. CPC H04L 1/0057

(57) ABSTRACT

Methods, systems, and devices for wireless communications are described that provide low density parity check (LDPC) coding techniques using a generated base graph that is generated from an initial base graph. The generated base graph may combine multiple punctured nodes of the initial base graph into a multiple degree node that merges element values of a first node and a second node of the initial base graph matrix, where the first node and the second node are punctured. The generated base graph may combine multiple punctured nodes of the initial base graph into a single node, and add a node to match a rate and code block size associated with the initial base graph.

### CROSS REFERENCE

The present Application for Patent claims the benefit of U.S. Provisional Patent Application No. 63/746,089 by SEN et al., entitled “LOW DENSITY PARITY CHECK TECHNIQUES IN WIRELESS COMMUNICATIONS,” filed Jan. 16, 2025, assigned to the assignee hereof, and which is expressly incorporated by reference herein.

### FIELD OF TECHNOLOGY

The following relates to wireless communications, including low density parity check techniques in wireless communications.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM).

A wireless multiple-access communications system may include one or more base stations, each supporting wireless communication for communication devices, which may be known as user equipment (UE).

### SUMMARY

The systems, methods, and devices of this disclosure each have several innovative aspects, no single one of which is solely responsible for the desirable attributes disclosed herein.

A method for wireless communications by a wireless device is described. The method may include obtaining a set of information bits to be transmitted from the wireless device, generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column of and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted, and transmitting a codeword based on the set of information bits and the parity check matrix.

A wireless device for wireless communications is described. The wireless device may include one or more memories storing processor executable code, and one or more processors coupled with the one or more memories. The one or more processors may individually or collectively be operable to execute the code to cause the wireless device to obtain a set of information bits to be transmitted from the wireless device, generate a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column of and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted, and transmit a codeword based on the set of information bits and the parity check matrix.

Another wireless device for wireless communications is described. The wireless device may include means for obtaining a set of information bits to be transmitted from the wireless device, means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column of and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted, and means for transmitting a codeword based on the set of information bits and the parity check matrix.

A non-transitory computer-readable medium storing code for wireless communications is described. The code may include instructions executable by one or more processors to obtain a set of information bits to be transmitted from the wireless device, generate a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column of and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted, and transmit a codeword based on the set of information bits and the parity check matrix.

In some examples of the method, wireless devices, and non-transitory computer-readable medium described herein, the first column of the generated base graph matrix merges a degree of each corresponding element of the first column of the initial base graph matrix and the second column of the initial base graph matrix, and both the first column of the initial base graph matrix and the second column of the initial base graph matrix are punctured columns.

In some examples of the method, wireless devices, and non-transitory computer-readable medium described herein, the circulant identity matrix may be a Z by Z identity matrix that is shifted in accordance with a cyclic shift value of a corresponding element of the generated base graph matrix, and where values of cyclic shifts associated with double edges in the first column of the generated base graph matrix are selected such that the cyclic shift values are not equal under modulo Z for each available value of Z.

In some examples of the method, wireless devices, and non-transitory computer-readable medium described herein, the first column of the generated base graph matrix merges a degree of each corresponding element of the first column of the initial base graph matrix and the second column of the initial base graph matrix, the first column of the generated base graph matrix is a punctured column and the second column of the generated base graph matrix is an unpunctured column that corresponds to the second column of the initial base graph matrix or is a generated column that is based on elements of the first column of the initial base graph matrix and the second column of the initial base graph matrix, and remaining columns of the generated base graph matrix other than the first column and the second column are unpunctured columns.

In some examples of the method, wireless devices, and non-transitory computer-readable medium described herein, the circulant identity matrix is a Z by Z identity matrix that is shifted in accordance with a cyclic shift value of a corresponding element of the generated base graph matrix, and where available values for Z are selected based on a quantity of edges of the generated base graph matrix, where an edge of the generated base graph matrix corresponds to an element of the generated base graph matrix that has an adjacent non-zero element of the generated base graph matrix.

In some examples of the method, wireless devices, and non-transitory computer-readable medium described herein, a dimension of the circulant identity matrix is Z×Z, and where a total size of the parity check matrix is a size of the generated base graph matrix multiplied by Z.

A method for wireless communications by a wireless device is described. The method may include obtaining a set of information bits to be transmitted from the wireless device, generating a parity check matrix based on the set of information bits, the parity check matrix including a base graph matrix and a lifted matrix, generating a codeword for transmission that includes systematic bits that correspond to the set of information bits and parity bits that are generated from the parity check matrix, mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation, and transmitting the codeword to a receiving device.

A wireless device for wireless communications is described. The wireless device may include one or more memories storing processor executable code, and one or more processors coupled with the one or more memories. The one or more processors may individually or collectively be operable to execute the code to cause the wireless device to obtain a set of information bits to be transmitted from the wireless device, generate a parity check matrix based on the set of information bits, the parity check matrix including a base graph matrix and a lifted matrix, generate a codeword for transmission that includes systematic bits that correspond to the set of information bits and parity bits that are generated from the parity check matrix, map the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation, and transmit the codeword to a receiving device.

Another wireless device for wireless communications is described. The wireless device may include means for obtaining a set of information bits to be transmitted from the wireless device, means for generating a parity check matrix based on the set of information bits, the parity check matrix including a base graph matrix and a lifted matrix, means for generating a codeword for transmission that includes systematic bits that correspond to the set of information bits and parity bits that are generated from the parity check matrix, means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation, and means for transmitting the codeword to a receiving device.

A non-transitory computer-readable medium storing code for wireless communications is described. The code may include instructions executable by one or more processors to obtain a set of information bits to be transmitted from the wireless device, generate a parity check matrix based on the set of information bits, the parity check matrix including a base graph matrix and a lifted matrix, generate a codeword for transmission that includes systematic bits that correspond to the set of information bits and parity bits that are generated from the parity check matrix, map the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation, and transmit the codeword to a receiving device.

In some examples of the method, wireless devices, and non-transitory computer-readable medium described herein, the check column is a last column of the base graph matrix, and the codeword is mapped to the modulation constellation such that the check column and one or more initial columns of the base graph matrix that correspond to the systematic bits are mapped to the MSB of the modulation constellation.

In some examples of the method, wireless devices, and non-transitory computer-readable medium described herein, the check column is moved to an initial column of the base graph matrix, and the codeword is mapped to the modulation constellation in accordance with an order of the non-punctured columns of the base graph matrix.

In some examples of the method, wireless devices, and non-transitory computer-readable medium described herein, copies of transmitted bits associated with each column of the base graph matrix have a corresponding channel reliability in accordance with the mapping of the codeword to the modulation constellation, and transmitted bits associated with different columns of the base graph matrix may have different channel reliabilities in accordance with the mapping of the codeword to the modulation constellation.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of a wireless communications system that supports low density parity check techniques in wireless communications in accordance with one or more aspects of the present disclosure.

FIG. 2 shows an example of a wireless communications system that supports low density parity check techniques in wireless communications in accordance with one or more aspects of the present disclosure.

FIG. 3 shows an example of a base graph that supports low density parity check techniques in wireless communications in accordance with one or more aspects of the present disclosure.

FIG. 4 shows another example of a base graph that supports low density parity check techniques in wireless communications in accordance with one or more aspects of the present disclosure.

FIG. 5 shows an example of a prioritized coded bit mapping scheme that supports low density parity check techniques in wireless communications in accordance with one or more aspects of the present disclosure.

FIGS. 6 and 7 show block diagrams of devices that support low density parity check techniques in wireless communications in accordance with one or more aspects of the present disclosure.

FIG. 8 shows a block diagram of a communications manager that supports low density parity check techniques in wireless communications in accordance with one or more aspects of the present disclosure.

FIG. 9 shows a diagram of a system including a network entity that supports low density parity check techniques in wireless communications in accordance with one or more aspects of the present disclosure.

FIG. 10 shows a diagram of a system including a UE that supports low density parity check techniques in wireless communications in accordance with one or more aspects of the present disclosure.

FIGS. 11 and 12 show flowcharts illustrating methods that support low density parity check techniques in wireless communications in accordance with one or more aspects of the present disclosure.

### DETAILED DESCRIPTION

Some wireless communications systems may implement error correcting codes to transmit signals over noisy communications channels, such as low-density parity-check (LDPC) codes. LDPC codes may be defined by a base graph and a lifting operation performed on the base graph using a circulant identity matrix to create a quantity of copies of the base graph. The base graph may be defined by variable nodes (e.g., columns) and check nodes (rows). Entries of the base graph may correspond to edges between the variable nodes and the check nodes. For example, if an entry of the base graph between a first variable node and a first check node has a value of one, there may be an edge between the first variable node and the first check node. A degree of a variable node may correspond to a total quantity of edges for the variable node. Devices within the wireless communications systems may implement modulation operations, such as lower-order modulation operations (quadrature phase-shift keying (QPSK) modulation) and higher-order modulation operations (e.g., quadrature amplitude modulation (QAM) modulation) to map the multiple information bits to a modulation constellation. The base graph may be a small graph that corresponds to macroscopic properties of the code and may, in some examples, be referred to as a protograph. The lifting procedure may correspond to lifting, or replacing, each entry of the base graph with a circulant identity matrix, or an identity matrix which has been cyclically shifted. For example, the lifting procedure may copy the base graph multiple times (e.g., corresponding to a size of the identity matrices) and connecting the different copies of the base graph via edge permutation. In some systems, a base graph may be designed for asymptotic performance, and a device may perform a relatively large quantity of iterations to achieve reliable decoding. Base graphs in some systems may include two punctured nodes (e.g., two punctured variable nodes), as a large degree of punctured nodes may correspond to improved asymptotic performance. However, having two punctured nodes may slow down convergence for high throughput applications. For punctured nodes to achieve a threshold reliability, a device may perform a large quantity of iterations. Further, as throughput increases, computing resources increase, and a doubled throughput needs a corresponding doubled computing capability and doubled energy consumption (assuming a fixed processing node size). Channel coding associated with error correcting codes may consume a relatively large amount of this capability, and thus techniques to reduce computing resources associated with channel coding may be desirable.

Various aspects of the present disclosure are related to LDPC coding techniques. More specifically, aspects of the present disclosure are related to LDPC coding techniques using a generated base graph that is generated from an initial base graph. In some aspects, the generated base graph may combine multiple punctured nodes of the initial base graph into a multiple degree node that merges element values of a first node and a second node of the initial base graph matrix, where the first node and the second node are punctured. In other aspects, the generated base graph may combine multiple punctured nodes of the initial base graph into a single node, and add a node to match a rate and code block size associated with the initial base graph. The multiple degree node may provide faster convergence, and may thereby reduce processing resources needed to obtain convergence. The transmitting device may perform a lifting procedure on the base graph, and in some examples may use lifting sizes (e.g., Z values) that provide that double edge liftings are not equal under modulo Z. Additionally, or alternatively, the transmitting device may map coded bits to a modulation constellation such that systematic bits, and bits of a special check node of the parity check matrix associated with a punctured node, are transmitted in higher-reliability portions of the modulation constellation. Such mappings may provide higher reliability for the systematic bits and the special check node bits, and may thereby enhance reliability of higher modulation order communications.

Aspects of the disclosure are initially described in the context of wireless communications systems. Aspects of the disclosure are further illustrated by and described with reference to base graphs, bit mappings for modulation constellations, apparatus diagrams, system diagrams, and flowcharts that relate to low density parity check techniques in wireless communications.

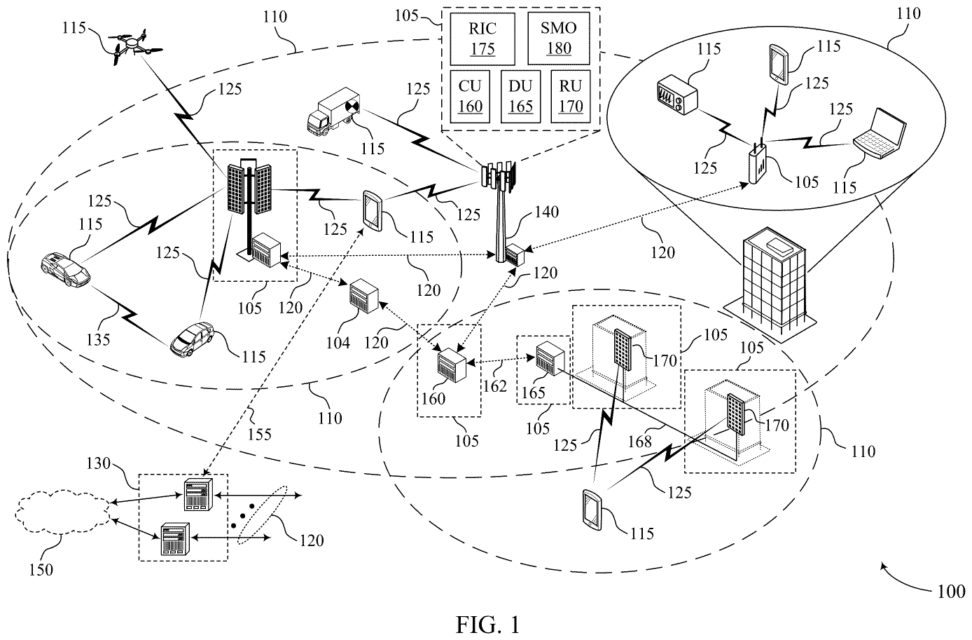

FIG. 1 shows an example of a wireless communications system 100 that supports low density parity check techniques in wireless communications in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3(L 3 ), layer 2 (L2)) functionality and signaling (e.g., Radio Resource Control (RRC), service data adaptation protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1(L 1 ) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support low density parity check techniques in wireless communications as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfmax may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

Some wireless communications systems may support high throughput. However, higher throughput may increase complexity at transmitting devices and receiving devices. For example, increasing throughput two-fold may require twice the computing capability at the receiver, which may correspond to twice the modem area and energy consumption. One significant factor in complexity may be channel decoding. As such, channel decoding techniques that are designed for throughput scaling may be desirable.

Some wireless communications systems may use quasi-cyclic LDPC codes. The code may be described by a base graph and liftings (e.g., protograph LDPC code). The base graph may be a small graph that captures the macroscopic properties of the code (e.g., the threshold). The base graph may be represented by a matrix (e.g., a base matrix), with columns corresponding to variable nodes of the base graph and rows corresponding to check nodes of the base graph. A transmitting device may perform a lifting procedure on the base graph. For example, each entry in the base matrix may be lifted by a circulant identity matrix, or a circularly shifted identity matrix, to generate a lifted matrix. In some examples, the lifting operation may refer to copying the base graph Z times and connecting the Z copies of the base graph via edge permutation. Circulant may be denoted by an integer in the non-zero entries of the base graph matrix. The dimension of the identity matrix may be Z×Z, where each variable node in the base graph is associated with Z coded bits from the LDPC code. A degree of a variable node may denote a quantity of check nodes that the variable node is connected to in the base graph (e.g., a total quantity of edges or ones in the column of the base graph). Lifting may preserve the degree distribution of each coded bit.

In some systems, a base graph may be designed for asymptotic performance. Base graphs in some systems may include two punctured nodes (e.g., two punctured variable nodes), as a large degree of punctured nodes may correspond to improved asymptotic performance. However, having two punctured nodes may slow down convergence for high throughput applications. For punctured nodes to achieve a threshold reliability, a device may perform a relatively large quantity of iterations.

The wireless communications system 100 may support LDPC coding techniques using a generated base graph that is based on an initial base graph. In some aspects, the generated base graph may combine multiple punctured nodes of the initial base graph into a multiple degree node that merges element values of a first node and a second node of the initial base graph matrix, where the first node and the second node are punctured. It is noted that a node may also be referred to as a column of the base graph, and the terms “node” and “column” are used interchangeably herein. In other aspects, the generated base graph may combine multiple punctured nodes of the initial base graph into a single node, and add a node to match a rate and code block size associated with the initial base graph. The multiple degree node may provide faster convergence, and may thereby reduce processing resources needed to obtain convergence. The transmitting device may perform a lifting procedure on the base graph, and in some examples may use lifting sizes (e.g., Z values) that provide that double edge liftings are not equal under modulo Z. Additionally, or alternatively, the transmitting device may map coded bits to a modulation constellation such that systematic bits, and bits of a special check node of the parity check matrix associated with a punctured node, are transmitted in higher-reliability portions of the modulation constellation. Such mappings may provide higher reliability for the systematic bits and the special check node bits, and may thereby enhance reliability of higher modulation order communications.

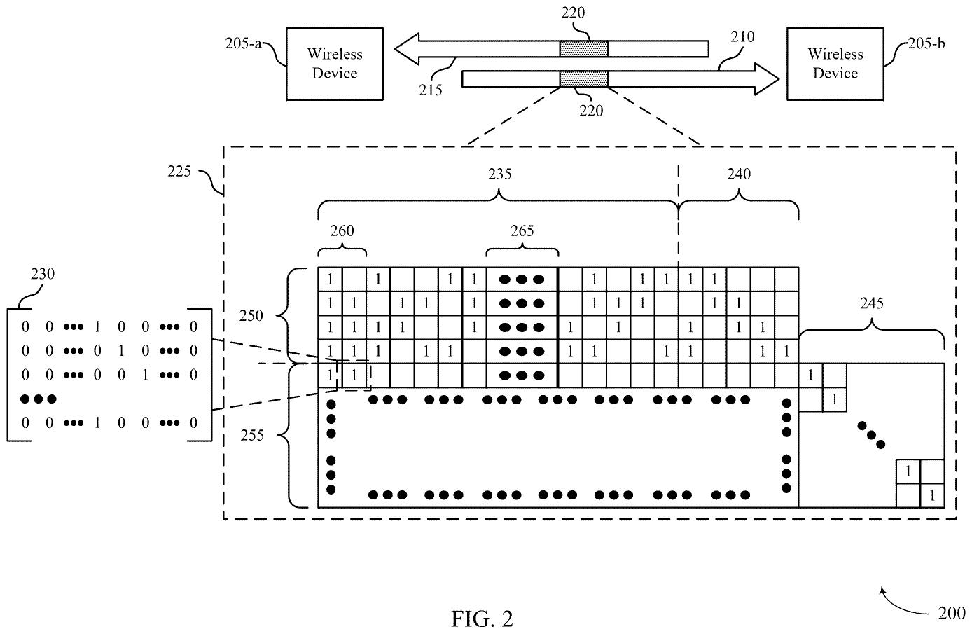

FIG. 2 shows an example of a wireless communications system 200 that supports low density parity check techniques in wireless communications in accordance with one or more aspects of the present disclosure. The wireless communications system may implement aspects of the wireless communications system 100 or may be implemented by aspects of the wireless communications system 100. For example, the wireless communications system 200 may include a wireless device 205-a and a wireless device 205-b, which may be examples of corresponding devices described herein (e.g., a network entity 105, a UE 115). The wireless device 205-a may communicate with the wireless device 205-b via the communication link 210 and the communication link 215. The communication link 210 and the communication link 215 may be either the uplink or the downlink, and in some cases may be a sidelink connection. A device transmitting a signal 220, or a message, (e.g., in the uplink, downlink, or sidelink) may be referred to as a transmitting device, and a device receiving the signal 220 (e.g., in the uplink, downlink, or sidelink) may be referred to as a receiving device.

The wireless communications system 200 may implement forward error correction (FEC) to reduce transmission errors when performing communications over unreliable or noisy channels. In some examples, the wireless device 205-a may be a transmitting device and may transmit a signal to the wireless device 205-b, which may be a receiving device, according to an error correction code. For example, the wireless device 205-a may transmit a signal 220 using an LDPC code (e.g., a quasi-cyclic (QC) LDPC code). The LDPC code may be described or defined by a base graph 225 (e.g., a protograph) and a lifting matrix 230. The base graph 225 may capture (e.g., represent) the macroscopic properties of the LDPC code (e.g., a threshold).

In some examples, the base graph 225 may be represented as a matrix (e.g., a base matrix). The base graph 225 may include multiple columns and multiple rows. Each column of the multiple columns of the base graph 225 may denote (e.g., be defined as) a variable node, and each row of the multiple rows of the base graph 225 may denote (e.g., may be defined as) a check node. The multiple variable nodes of the base graph 225 may further include multiple information nodes 235, multiple core parity nodes 240, and multiple extension parity nodes 245. The multiple check nodes of the base graph 225 may include multiple core check nodes 250 and multiple extension check nodes 255. Each variable node may be associated with a degree, which may denote a quantity of check nodes associated with each variable node. For example, the degree associated with a variable node may indicate that the variable node is associated with a quantity of edges of the base graph 225 (e.g., non-zero elements of the variable node). In some cases, one or more variable nodes of the base graph 225 may be punctured information nodes (e.g., a non-transmitted node). For example, the first and second nodes 260 may be punctured information nodes Additionally, or alternatively, the multiple information nodes 235 may include one or more special extension check nodes 265.

The LDPC code may be further described by a lifting matrix 230. For example, the LDPC code may be described by a circulant identity matrix, and the wireless device 205-a, the wireless device 205-b, or both the wireless device 205-a and the wireless device 205-b may lift (e.g., perform a lifting operation) each entry of the base graph 225 according to the circulant identity matrix, which may be a Z by Z matrix (e.g., where Z≤384). The cyclic shift associated with the circulant identity matrix may be indicated by a non-zero value in the base graph 225. In some examples, each variable node of the base graph 225 may be associated with a quantity of coded bits associated with the LDPC code, and the dimensions of the lifting matrix 230 (e.g., width, height, or both) may be equal to the quantity of coded bits. In such examples, the wireless device 205-b, or both the wireless device 205-a and the wireless device 205-b may create a quantity of copies of the base graph 225 equal to the quantity of coded bits and may connect the quantity of copies of the base graph 225 via edge permutation. A total block length may be the base graph 225 size times the lift value (Z). By performing the lifting operation, the wireless device 205-b, or both the wireless device 205-a and the wireless device 205-b may preserve a degree distribution of each coded bit.

In some aspects, the wireless device 205-a and the wireless device 205-b may perform a higher-order modulation operation (e.g., 256 QAM) to map the coded bits to a modulation constellation in accordance with a systematic bit prioritized mapping (SBPM) scheme. The SBPM scheme may map the systematic portion of the coded bits (e.g., information bits) to one or more most significant bits (MSBs) of the modulation constellation, and may map the non-systematic portion of the coded bits (e.g., parity bits) to one or more least significant bits (LSBs) of the modulation constellation. Such techniques may provide that copies of the same variable nodes in the base graph 225 experience similar channel reliabilities and different variable nodes in the base graph 225 may experience different channel reliabilities, and thus may generally improve the decoding threshold of quasi-cyclic LDPC.

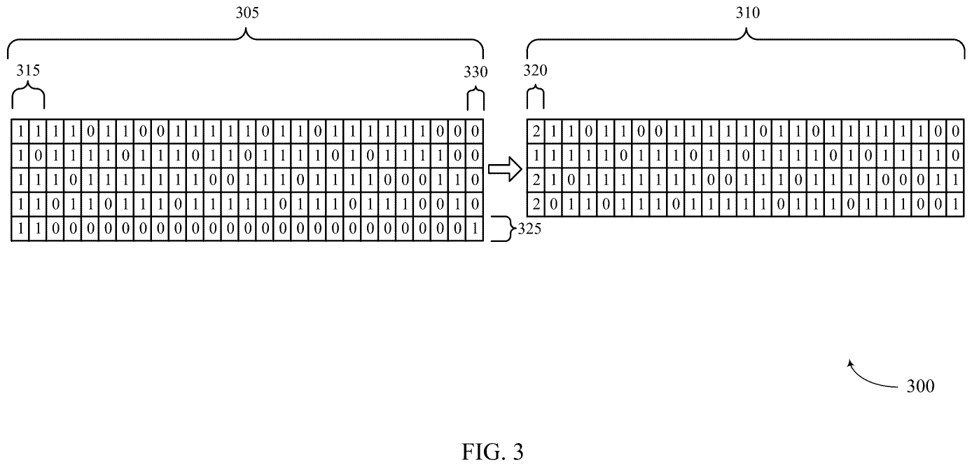

In some examples, as described herein with reference to FIGS. 3-5, the wireless device 205-a may generate an LDPC code according to a base graph, which may be defined by variable nodes (e.g., columns of the base graph 225) and check nodes (e.g., rows of the base graph 225). In some aspects, the base graph may be generated from an initial base graph by combining multiple punctured nodes of the initial base graph into a multiple degree node that merges element values of the punctured nodes of the initial base graph matrix. In some aspects, the generated base graph may combine multiple punctured nodes of the initial base graph into a single node, and add a node to match a rate and code block size associated with the initial base graph.

FIG. 3 shows an example of a base graph 300 that supports low density parity check techniques in wireless communications in accordance with one or more aspects of the present disclosure. The base graph 300 may implement or be implemented by aspects of the wireless communications system 100 or the wireless communications system 200. For example, transmissions between two wireless devices (which may be examples of wireless devices 205 as described herein with reference to FIG. 2) may be encoded according to an LDPC code. In such examples, a transmitting device may transmit a signal including one or more coded bits to a receiving device based on encoding the signal. The receiving device may decode the signal based on receiving the signal and generating an LDPC code associated with the signal.

The transmitting device may generate the LDPC code based on an initial base graph 305 that is used to generate a generated base graph 310. The initial base graph 305 may include one or more variable nodes, including two punctured variable nodes 315, which may be in a first and a second node position. Further, the initial base graph 305 may include a fifth row, which may be a special extension row 325, and a special check node 330, that may be used for determining one or more of the punctured variable nodes 315. In some aspects, the generated base graph 310 may merge the multiple punctured variable nodes 315 of the initial base graph 305 into a single punctured node 320. Since a single punctured node 320 is provided in the generated base graph 310, the special extension row 325 is not provided in the generated base graph 310. In some aspects, the generated base graph 310 may use a same lifting as the initial base graph 305. In some aspects, merging the punctured variable nodes 315 into a single multiple degree punctured node 320, and removing the special extension row 325, results in losing one information column and reduces a data transmission rate for the encoded data slightly. For example, for the initial base graph 305 the rate would be 22/x, where x denotes the number of transmitted columns, and for the generated base graph 310 the rate would be vs 21/(x−1). For example, if x=25, the rate for the initial base graph 305 would be 22/25=0.88 versus a rate for the generated base graph of 21/24=0.875. In some aspects, performance improvements from faster convergence associated with the generated base graph 310 may be substantial enough that the slightly reduced rate is acceptable. In some aspects, a maximum rate and a maximum code block (CB) size may be defined for the generated base graph 310. In some aspects, lifting values associated with the initial base graph 305 may be reused for the corresponding edges in the generated base graph 310 as long as the double edge liftings are not equal under modulo Z. Further, if lifting is performed with nested Z, the two lifting values on a given double edge may be provided such that they are not equal under modulo operation with respect to all the supported Z values.

In accordance with various aspects, the generated base graph 310 may converge faster than other base graphs (e.g., the initial base graph 305 or other base graphs with multiple punctured nodes) and may match asymptotically. As described herein, each of the one or more variable nodes may be associated with a degree. In such cases, a numerical value associated with each degree may indicate that each of the one or more variable nodes is associated with a quantity of check nodes similar to (e.g., equal to) the numerical value associated with each degree. In this example, the single multiple degree punctured node 320 may be associated with two check nodes (e.g., second degree nodes) or more. In an example, the single multiple degree punctured node 320 may have a degree of seven based on having three double-edged elements and one single-edged element. The punctured node may provide threshold improvement. For example, the punctured node may increase the check node degree of the transmitted graph.

In some aspects, a transmitting device and a receiving device may exchange signaling that indicates whether the initial base graph 305 or the generated base graph 310 is to be used for LDPC encoding of shared channel transmissions. In some aspects, for example, a UE may provide a capability indication that indicates a capability to use either base graph, and a network entity may select a base graph to use for subsequent communications and indicate the selection to the UE (e.g. via radio resource control (RRC) signaling, a medium access control (MAC) control element, a downlink control information (DCI) transmission, or any combination thereof).

In some aspects, communications using the initial base graph 305 and the generated base graph 310 may use the same hardware. For example, a same encoder may be used (without special check node 330) with input Z information bits plus copies of Z (to be shortened at transmission)+20Z information bits to compute the parity, and transmit the information bits (without the Z copies) followed by parity bits. In other aspects, a transmitting device or a receiving device may implement the initial base graph 305 or the generated base graph 310, or both, using dedicated hardware or a hardware implementation associated with the initial base graph 305 or the generated base graph 310, or both.

A receiving device may receive a signal including information bits and parity bits according to the LDPC code. In some examples, the receiving device may generate the LDPC code according to a lifted graph. The lifted graph may include multiple connected copies of the base graph that are connected via edge permutation based on a lifting procedure. The receiving device may attempt to decode the information bits based on the parity bits, information nodes, and parity nodes. In some examples, the receiving device may perform layered decoding to decode the information bits. For example, the receiving device may decode single edge layers first then decode double edge layers. For example, the receiving device may decode the first and second layers (e.g., rows) of a base graph, then the receiving device may decode the third and fourth layers of the base graph. In some examples, the receiving device may start decoding from a lowest degree layer and finish decoding with a highest degree layer. In some examples, the receiving device may not connect a variable node to the parity checks that are decoded consecutively in the layered decoding. For example, a message update may not be ready based on a pipeline of the bits or the implementation. In some examples, asymmetric degree distribution for parity check nodes may assist layered decoding. In some examples, the base graph may support degree one extension structure to assist decoding operations at the receiving device.

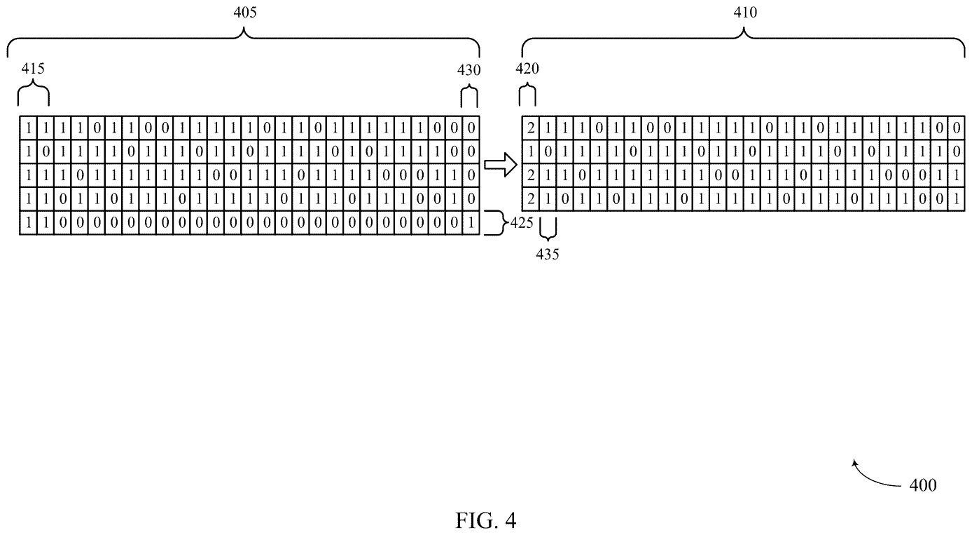

FIG. 4 shows an example of a base graph 400 that supports low density parity check techniques in wireless communications in accordance with one or more aspects of the present disclosure. The base graph 400 may implement or be implemented by aspects of the wireless communications system 100 or the wireless communications system 200. For example, transmissions between two wireless devices (which may be examples of wireless devices 205 as described herein with reference to FIG. 2) may be encoded according to an LDPC code. In such examples, a transmitting device may transmit a signal including one or more coded bits to a receiving device based on encoding the signal. The receiving device may decode the signal based on receiving the signal and generating an LDPC code associated with the signal.

The transmitting device may generate the LDPC code based on an initial base graph 405 that is used to generate a generated base graph 410. Similarly as discussed with reference to FIG. 3, the initial base graph 405 may include one or more variable nodes, including two punctured variable nodes 415, which may be in a first and a second node position. Further, the initial base graph 405 may include a fifth row, which may be a special extension row 425, and a special extension node 430, that may be used for determining one or more of the punctured variable nodes 415. In some aspects, the generated base graph 410 may merge the multiple punctured variable nodes 415 of the initial base graph 405 into a single punctured node 420. Since a single punctured node 420 is provided in the generated base graph 410, the special extension row 425 is not provided in the generated base graph 410. In aspects such as illustrated in FIG. 4, the single punctured node 420 may be provided, along with an added extra column(s) 435 to match the rate and maximum CB size of the initial base graph 405. In some examples, the added extra column(s) may be provided by unpuncturing one (or more) of the punctured variable nodes 415 except the first punctured node, and adding those unpunctured columns to the single punctured node 420 (providing a single punctured node with multiple degree column), which will provide a same maximum rate and maximum CB size for the initial base graph 405 and the generated base graph 410. In such aspects, different lifting or a same lifting as the initial base graph 405 may be used, which may be optimized for the added edges of the generated base graph 410.

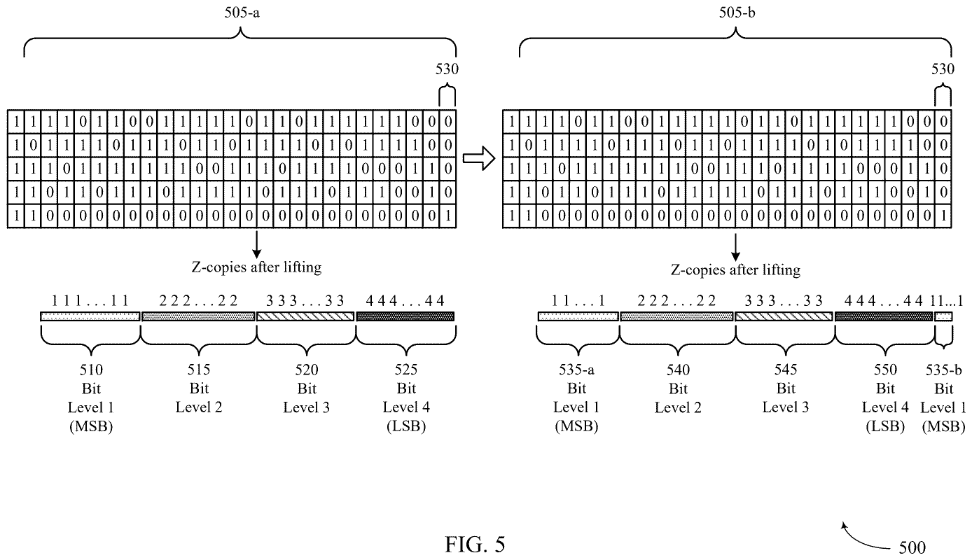

FIG. 5 shows an example of a prioritized coded bit mapping scheme 500 that supports low density parity check techniques in wireless communications in accordance with one or more aspects of the present disclosure. The prioritized coded bit mapping scheme 500 may implement or be implemented by aspects of the wireless communications system 100 or the wireless communications system 200, or the base graphs of FIG. 3 or 4. For example, transmissions between two wireless devices (which may be examples of wireless devices 205 as described herein with reference to FIG. 2) may be encoded according to an LDPC code. In such examples, a transmitting device may transmit a signal including one or more coded bits to a receiving device based on encoding the signal. The receiving device may decode the signal based on receiving the signal and generating an LDPC code associated with the signal.

In some aspects, the transmitting device may map the elements of a base graph 505 (e.g., one or more information bits, and one or more parity bits) to different bits of a modulation constellation. In a first example, for the base graph 505-a, a first set of variable nodes 510 may correspond to a first MSB of the modulation constellation, a second set of variable nodes 515 may correspond to a second MSB of the modulation constellation, a third set of variable nodes 520 may correspond to a third MSB of the modulation constellation, and a fourth set of variable nodes 525 may correspond to the LSB of the modulation constellation.

As discussed herein, in some aspects a special check node 530 may be used. In a second example, in order to enhance the reliability of the special check node 530, this node may be mapped to a MSB of the modulation constellation. For example, for the base graph 505-b, a first subset of the first set of variable nodes 535-a and a second subset of the first set of variable nodes 535-b may correspond to the first MSB of the modulation constellation, a second set of variable nodes 540 may correspond to the second MSB of the modulation constellation, a third set of variable nodes 545 may correspond to a third MSB of the modulation constellation, and a fourth set of variable nodes 550 may correspond to the LSB of the modulation constellation. In other aspects, the special check node 530 may be moved to the beginning of the base graph, and mapping in accordance with the first example of base graph 505-a may be used.

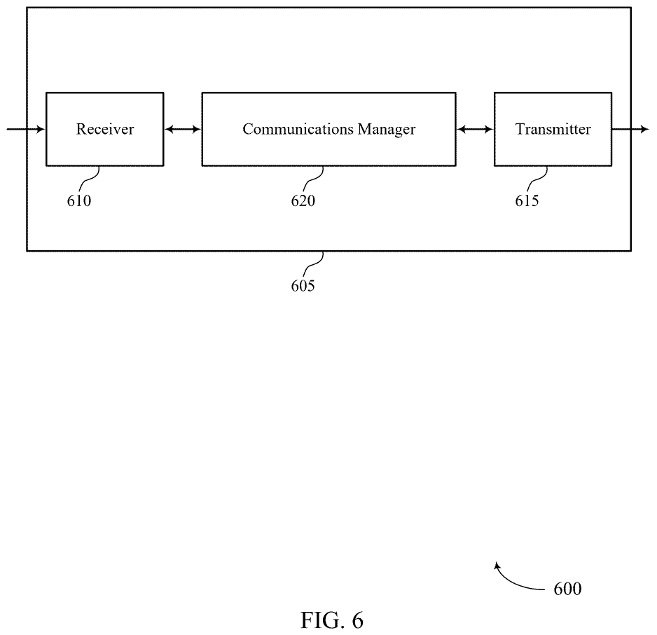

FIG. 6 shows a block diagram 600 of a device 605 that supports low density parity check techniques in wireless communications in accordance with one or more aspects of the present disclosure. The device 605 may be an example of aspects of a UE 115 or a network entity 105 as described herein. The device 605 may include a receiver 610, a transmitter 615, and a communications manager 620. The device 605, or one or more components of the device 605 (e.g., the receiver 610, the transmitter 615, the communications manager 620), may include at least one processor, which may be coupled with at least one memory, to, individually or collectively, support or enable the described techniques. Each of these components may be in communication with one another (e.g., via one or more buses).

The receiver 610 may provide a means for receiving information such as packets, user data, control information, or any combination thereof associated with various information channels (e.g., control channels, data channels, information channels related to low density parity check techniques in wireless communications). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to low density parity check techniques in wireless communications). In some examples, the transmitter 615 may be co-located with a receiver 610 in a transceiver module. The transmitter 615 may utilize a single antenna or a set of multiple antennas.

The communications manager 620, the receiver 610, the transmitter 615, or various combinations or components thereof may be examples of means for performing various aspects of low density parity check techniques in wireless communications as described herein. For example, the communications manager 620, the receiver 610, the transmitter 615, or various combinations or components thereof may be capable of performing one or more of the functions described herein.

In some examples, the communications manager 620, the receiver 610, the transmitter 615, or various combinations or components thereof may be implemented in hardware (e.g., in communications management circuitry). The hardware may include at least one of a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 620, the receiver 610, the transmitter 615, or various combinations or components thereof may be implemented in code (e.g., as communications management software or firmware) executed by at least one processor (e.g., referred to as a processor-executable code). If implemented in code executed by at least one processor, the functions of the communications manager 620, the receiver 610, the transmitter 615, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 620 may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications in accordance with examples as disclosed herein. For example, the communications manager 620 is capable of, configured to, or operable to support a means for obtaining a set of information bits to be transmitted from the wireless device. The communications manager 620 is capable of, configured to, or operable to support a means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The communications manager 620 is capable of, configured to, or operable to support a means for transmitting a codeword based on the set of information bits and the parity check matrix.

Additionally, or alternatively, the communications manager 620 may support wireless communications in accordance with examples as disclosed herein. For example, the communications manager 620 is capable of, configured to, or operable to support a means for obtaining a set of information bits to be transmitted from the wireless device. The communications manager 620 is capable of, configured to, or operable to support a means for generating a parity check matrix based on the set of information bits, the parity check matrix including a base graph matrix and a lifted matrix. The communications manager 620 is capable of, configured to, or operable to support a means for generating a codeword for transmission that includes systematic bits that correspond to the set of information bits and parity bits that are generated from the parity check matrix. The communications manager 620 is capable of, configured to, or operable to support a means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. The communications manager 620 is capable of, configured to, or operable to support a means for transmitting the codeword to a receiving device.

By including or configuring the communications manager 620 in accordance with examples as described herein, the device 605 (e.g., at least one processor controlling or otherwise coupled with the receiver 610, the transmitter 615, the communications manager 620, or a combination thereof) may support techniques for faster convergence for decoding LDPC codes, which may provide for efficient processing using less processing resources per decoding of CBs.

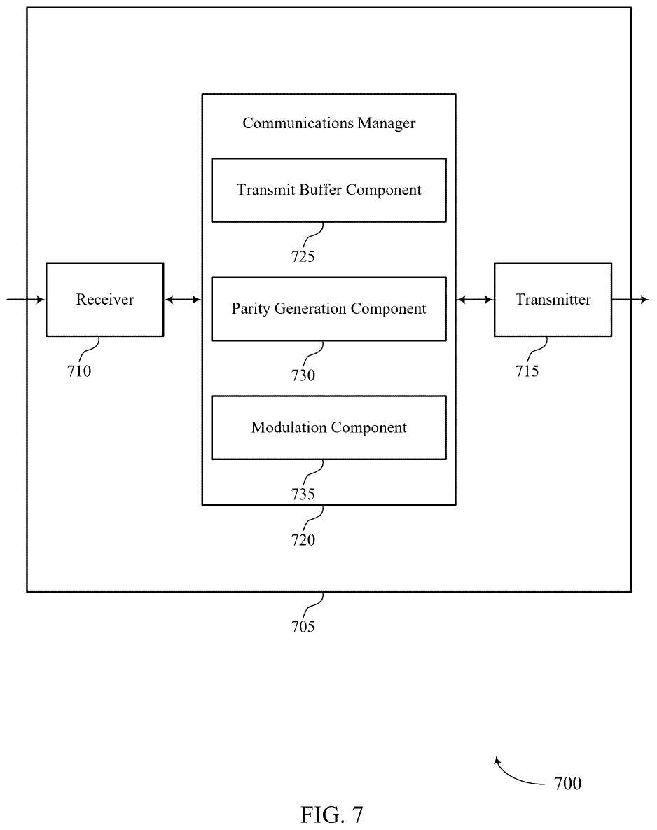

FIG. 7 shows a block diagram 700 of a device 705 that supports low density parity check techniques in wireless communications in accordance with one or more aspects of the present disclosure. The device 705 may be an example of aspects of a device 605, a UE 115, or a network entity 105 as described herein. The device 705 may include a receiver 710, a transmitter 715, and a communications manager 720. The device 705, or one or more components of the device 705 (e.g., the receiver 710, the transmitter 715, the communications manager 720), may include at least one processor, which may be coupled with at least one memory, to support the described techniques. Each of these components may be in communication with one another (e.g., via one or more buses).

The receiver 710 may provide a means for receiving information such as packets, user data, control information, or any combination thereof associated with various information channels (e.g., control channels, data channels, information channels related to low density parity check techniques in wireless communications). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to low density parity check techniques in wireless communications). In some examples, the transmitter 715 may be co-located with a receiver 710 in a transceiver module. The transmitter 715 may utilize a single antenna or a set of multiple antennas.

The device 705, or various components thereof, may be an example of means for performing various aspects of low density parity check techniques in wireless communications as described herein. For example, the communications manager 720 may include a transmit buffer component 725, a parity generation component 730, a modulation component 735, or any combination thereof. The communications manager 720 may be an example of aspects of a communications manager 620 as described herein. In some examples, the communications manager 720, or various components thereof, may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications in accordance with examples as disclosed herein. The transmit buffer component 725 is capable of, configured to, or operable to support a means for obtaining a set of information bits to be transmitted from the wireless device. The parity generation component 730 is capable of, configured to, or operable to support a means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The modulation component 735 is capable of, configured to, or operable to support a means for transmitting a codeword based on the set of information bits and the parity check matrix.

Additionally, or alternatively, the communications manager 720 may support wireless communications in accordance with examples as disclosed herein. The transmit buffer component 725 is capable of, configured to, or operable to support a means for obtaining a set of information bits to be transmitted from the wireless device. The parity generation component 730 is capable of, configured to, or operable to support a means for generating a parity check matrix based on the set of information bits, the parity check matrix including a base graph matrix and a lifted matrix. The modulation component 735 is capable of, configured to, or operable to support a means for generating a codeword for transmission that includes systematic bits that correspond to the set of information bits and parity bits that are generated from the parity check matrix. The modulation component 735 is capable of, configured to, or operable to support a means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. The modulation component 735 is capable of, configured to, or operable to support a means for transmitting the codeword to a receiving device.

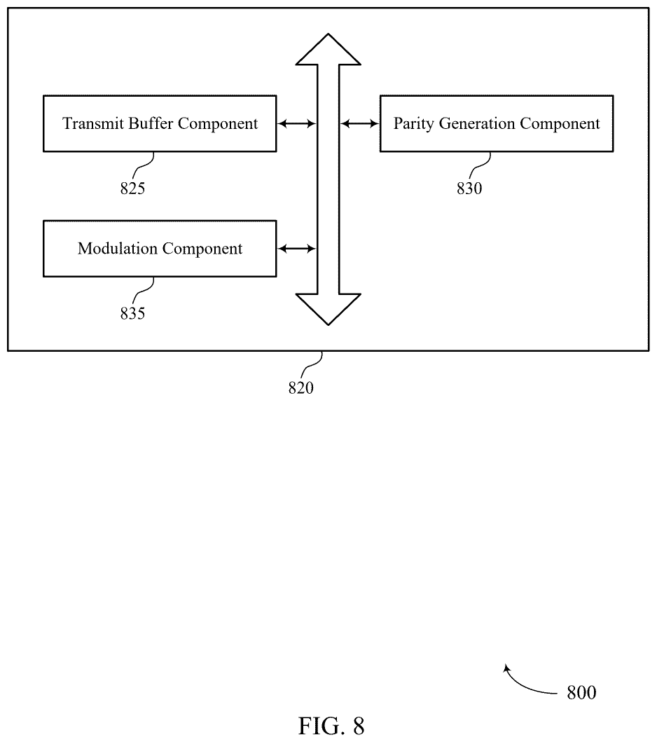

FIG. 8 shows a block diagram 800 of a communications manager 820 that supports low density parity check techniques in wireless communications in accordance with one or more aspects of the present disclosure. The communications manager 820 may be an example of aspects of a communications manager 620, a communications manager 720, or both, as described herein. The communications manager 820, or various components thereof, may be an example of means for performing various aspects of low density parity check techniques in wireless communications as described herein. For example, the communications manager 820 may include a transmit buffer component 825, a parity generation component 830, a modulation component 835, or any combination thereof. Each of these components, or components or subcomponents thereof (e.g., one or more processors, one or more memories), may communicate, directly or indirectly, with one another (e.g., via one or more buses). The communications may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 820 may support wireless communications in accordance with examples as disclosed herein. The transmit buffer component 825 is capable of, configured to, or operable to support a means for obtaining a set of information bits to be transmitted from the wireless device. The parity generation component 830 is capable of, configured to, or operable to support a means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The modulation component 835 is capable of, configured to, or operable to support a means for transmitting a codeword based on the set of information bits and the parity check matrix.

In some examples, the first column of the generated base graph matrix merges a degree of each corresponding element of the first column of the initial base graph matrix and the second column of the initial base graph matrix, and both the first column of the initial base graph matrix and the second column of the initial base graph matrix are punctured columns.

In some examples, the circulant identity matrix is a Z by Z identity matrix that is shifted in accordance with a cyclic shift value of a corresponding element of the generated base graph matrix, and wherein values of cyclic shifts associated with double edges in the first column of the generated base graph matrix are selected such that the cyclic shift values are not equal under modulo Z for each available value of Z.

In some examples, the first column of the generated base graph matrix merges a degree of each corresponding element of the first column of the initial base graph matrix and the second column of the initial base graph matrix. In some examples, the first column of the generated base graph matrix is a punctured column and the second column of the generated base graph matrix is an unpunctured column that corresponds to the second column of the initial base graph matrix or is a generated column that is based on elements of the first column of the initial base graph matrix and the second column of the initial base graph matrix. In some examples, remaining columns of the generated base graph matrix other than the first column and the second column are unpunctured columns.

In some examples, the circulant identity matrix is a Z by Z identity matrix that is shifted in accordance with a cyclic shift value of a corresponding element of the generated base graph matrix, and where available values for Z are selected based on a quantity of edges of the generated base graph matrix, where an edge of the generated base graph matrix corresponds to an element of the generated base graph matrix that has an adjacent non-zero element of the generated base graph matrix. In some examples, a dimension of the circulant identity matrix is Z×Z, and where a total size of the parity check matrix is a size of the generated base graph matrix multiplied by Z.

Additionally, or alternatively, the communications manager 820 may support wireless communications in accordance with examples as disclosed herein. In some examples, the transmit buffer component 825 is capable of, configured to, or operable to support a means for obtaining a set of information bits to be transmitted from the wireless device. In some examples, the parity generation component 830 is capable of, configured to, or operable to support a means for generating a parity check matrix based on the set of information bits, the parity check matrix including a base graph matrix and a lifted matrix. In some examples, the modulation component 835 is capable of, configured to, or operable to support a means for generating a codeword for transmission that includes systematic bits that correspond to the set of information bits and parity bits that are generated from the parity check matrix. In some examples, the modulation component 835 is capable of, configured to, or operable to support a means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. In some examples, the modulation component 835 is capable of, configured to, or operable to support a means for transmitting the codeword to a receiving device.

In some examples, the check column is a last column of the base graph matrix, and the codeword is mapped to the modulation constellation such that the check column and one or more initial columns of the base graph matrix that correspond to the systematic bits are mapped to the MSB of the modulation constellation.

In some examples, the check column is moved to an initial column of the base graph matrix, and the codeword is mapped to the modulation constellation in accordance with an order of the non-punctured columns of the base graph matrix.

In some examples, copies of transmitted bits associated with each column of the base graph matrix have a corresponding channel reliability in accordance with the mapping of the codeword to the modulation constellation, and transmitted bits associated with different columns of the base graph matrix may have different channel reliabilities in accordance with the mapping of the codeword to the modulation constellation.

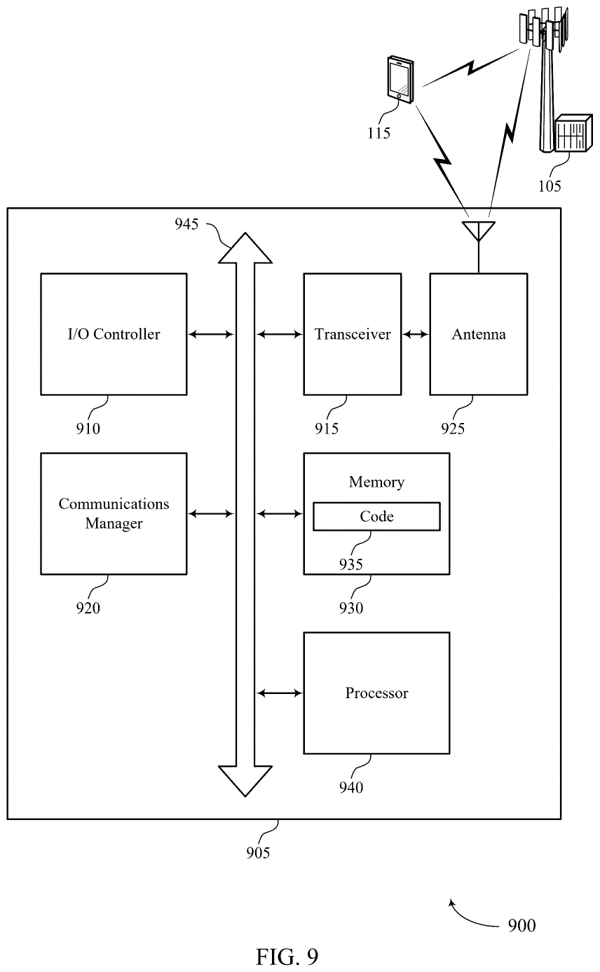

FIG. 9 shows a diagram of a system 900 including a device 905 that supports low density parity check techniques in wireless communications in accordance with one or more aspects of the present disclosure. The device 905 may be an example of or include components of a device 605, a device 705, or a UE 115 as described herein. The device 905 may communicate (e.g., wirelessly) with one or more other devices (e.g., network entities 105, UEs 115, or a combination thereof). The device 905 may include components for bi-directional voice and data communications including components for transmitting and receiving communications, such as a communications manager 920, an input/output (I/O) controller, such as an I/O controller 910, a transceiver 915, one or more antennas 925, at least one memory 930, code 935, and at least one processor 940. These components may be in electronic communication or otherwise coupled (e.g., operatively, communicatively, functionally, electronically, electrically) via one or more buses (e.g., a bus 945).

The I/O controller 910 may manage input and output signals for the device 905. The I/O controller 910 may also manage peripherals not integrated into the device 905. In some cases, the I/O controller 910 may represent a physical connection or port to an external peripheral. In some cases, the I/O controller 910 may utilize an operating system such as iOS®, ANDROID®, MS-DOS®, MS-WINDOWS®, OS/2®, UNIX®, LINUX®, or another known operating system. Additionally, or alternatively, the I/O controller 910 may represent or interact with a modem, a keyboard, a mouse, a touchscreen, or a similar device. In some cases, the I/O controller 910 may be implemented as part of one or more processors, such as the at least one processor 940. In some cases, a user may interact with the device 905 via the I/O controller 910 or via hardware components controlled by the I/O controller 910.

In some cases, the device 905 may include a single antenna. However, in some other cases, the device 905 may have more than one antenna, which may be capable of concurrently transmitting or receiving multiple wireless transmissions. The transceiver 915 may communicate bi-directionally via the one or more antennas 925 using wired or wireless links as described herein. For example, the transceiver 915 may represent a wireless transceiver and may communicate bi-directionally with another wireless transceiver. The transceiver 915 may also include a modem to modulate the packets, to provide the modulated packets to one or more antennas 925 for transmission, and to demodulate packets received from the one or more antennas 925. The transceiver 915, or the transceiver 915 and one or more antennas 925, may be an example of a transmitter 615, a transmitter 715, a receiver 610, a receiver 710, or any combination thereof or component thereof, as described herein.

The at least one memory 930 may include random access memory (RAM) and read-only memory (ROM). The at least one memory 930 may store computer-readable, computer-executable, or processor-executable code, such as the code 935. The code 935 may include instructions that, when executed by the at least one processor 940, cause the device 905 to perform various functions described herein. The code 935 may be stored in a non-transitory computer-readable medium such as system memory or another type of memory. In some cases, the code 935 may not be directly executable by the at least one processor 940 but may cause a computer (e.g., when compiled and executed) to perform functions described herein. In some cases, the at least one memory 930 may include, among other things, a basic I/O system (BIOS) which may control basic hardware or software operation such as the interaction with peripheral components or devices.

The at least one processor 940 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 940 may be configured to operate a memory array using a memory controller. In some other cases, a memory controller may be integrated into the at least one processor 940. The at least one processor 940 may be configured to execute computer-readable instructions stored in a memory (e.g., the at least one memory 930) to cause the device 905 to perform various functions (e.g., functions or tasks supporting low density parity check techniques in wireless communications). For example, the device 905 or a component of the device 905 may include at least one processor 940 and at least one memory 930 coupled with or to the at least one processor 940, the at least one processor 940 and the at least one memory 930 configured to perform various functions described herein.

In some examples, the at least one processor 940 may include multiple processors and the at least one memory 930 may include multiple memories. One or more of the multiple processors may be coupled with one or more of the multiple memories, which may, individually or collectively, be configured to perform various functions described herein. In some examples, the at least one processor 940 may be a component of a processing system, which may refer to a system (such as a series) of machines, circuitry (including, for example, one or both of processor circuitry (which may include the at least one processor 940) and memory circuitry (which may include the at least one memory 930)), or components, that receives or obtains inputs and processes the inputs to produce, generate, or obtain a set of outputs. The processing system may be configured to perform one or more of the functions described herein. For example, the at least one processor 940 or a processing system including the at least one processor 940 may be configured to, configurable to, or operable to cause the device 905 to perform one or more of the functions described herein. Further, as described herein, being “configured to,” being “configurable to,” and being “operable to” may be used interchangeably and may be associated with a capability, when executing code 935 (e.g., processor-executable code) stored in the at least one memory 930 or otherwise, to perform one or more of the functions described herein.

The communications manager 920 may support wireless communications in accordance with examples as disclosed herein. For example, the communications manager 920 is capable of, configured to, or operable to support a means for obtaining a set of information bits to be transmitted from the wireless device. The communications manager 920 is capable of, configured to, or operable to support a means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The communications manager 920 is capable of, configured to, or operable to support a means for transmitting a codeword based on the set of information bits and the parity check matrix.

Additionally, or alternatively, the communications manager 920 may support wireless communications in accordance with examples as disclosed herein. For example, the communications manager 920 is capable of, configured to, or operable to support a means for obtaining a set of information bits to be transmitted from the wireless device. The communications manager 920 is capable of, configured to, or operable to support a means for generating a parity check matrix based on the set of information bits, the parity check matrix including a base graph matrix and a lifted matrix. The communications manager 920 is capable of, configured to, or operable to support a means for generating a codeword for transmission that includes systematic bits that correspond to the set of information bits and parity bits that are generated from the parity check matrix. The communications manager 920 is capable of, configured to, or operable to support a means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. The communications manager 920 is capable of, configured to, or operable to support a means for transmitting the codeword to a receiving device.

By including or configuring the communications manager 920 in accordance with examples as described herein, the device 905 may support techniques for faster convergence for decoding LDPC codes, which may provide for efficient processing using less processing resources per decoding of CBs.

In some examples, the communications manager 920 may be configured to perform various operations (e.g., receiving, monitoring, transmitting) using or otherwise in cooperation with the transceiver 915, the one or more antennas 925, or any combination thereof. Although the communications manager 920 is illustrated as a separate component, in some examples, one or more functions described with reference to the communications manager 920 may be supported by or performed by the at least one processor 940, the at least one memory 930, the code 935, or any combination thereof. For example, the code 935 may include instructions executable by the at least one processor 940 to cause the device 905 to perform various aspects of low density parity check techniques in wireless communications as described herein, or the at least one processor 940 and the at least one memory 930 may be otherwise configured to, individually or collectively, perform or support such operations.

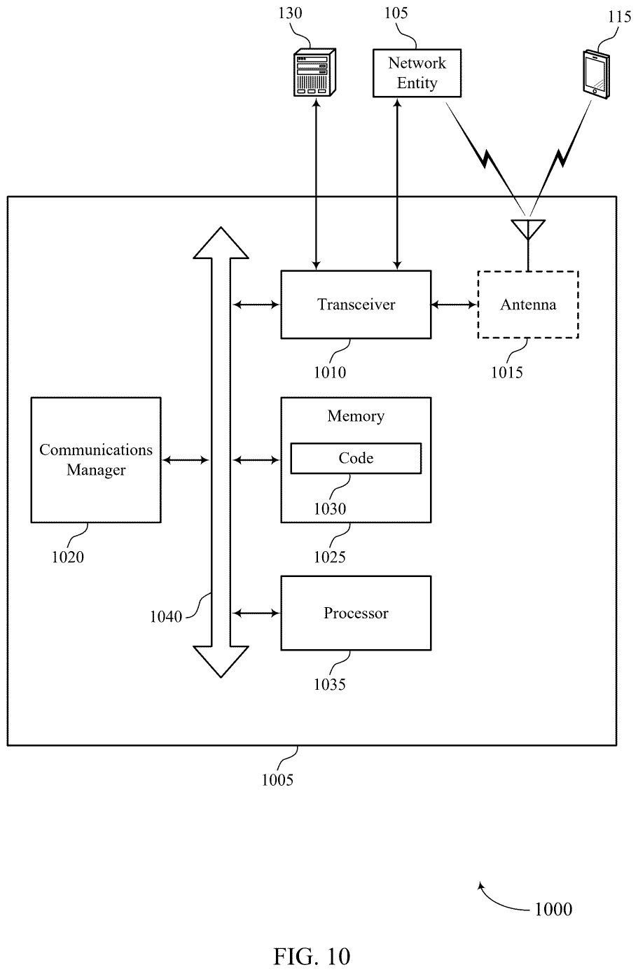

FIG. 10 shows a diagram of a system 1000 including a device 1005 that supports low density parity check techniques in wireless communications in accordance with one or more aspects of the present disclosure. The device 1005 may be an example of or include components of a device 605, a device 705, or a network entity 105 as described herein. The device 1005 may communicate with other network devices or network equipment such as one or more of the network entities 105, UEs 115, or any combination thereof. The communications may include communications over one or more wired interfaces, over one or more wireless interfaces, or any combination thereof. The device 1005 may include components that support outputting and obtaining communications, such as a communications manager 1020, a transceiver 1010, one or more antennas 1015, at least one memory 1025, code 1030, and at least one processor 1035. These components may be in electronic communication or otherwise coupled (e.g., operatively, communicatively, functionally, electronically, electrically) via one or more buses (e.g., a bus 1040).

The transceiver 1010 may support bi-directional communications via wired links, wireless links, or both as described herein. In some examples, the transceiver 1010 may include a wired transceiver and may communicate bi-directionally with another wired transceiver. Additionally, or alternatively, in some examples, the transceiver 1010 may include a wireless transceiver and may communicate bi-directionally with another wireless transceiver. In some examples, the device 1005 may include one or more antennas 1015, which may be capable of transmitting or receiving wireless transmissions (e.g., concurrently). The transceiver 1010 may also include a modem to modulate signals, to provide the modulated signals for transmission (e.g., by one or more antennas 1015, by a wired transmitter), to receive modulated signals (e.g., from one or more antennas 1015, from a wired receiver), and to demodulate signals. In some implementations, the transceiver 1010 may include one or more interfaces, such as one or more interfaces coupled with the one or more antennas 1015 that are configured to support various receiving or obtaining operations, or one or more interfaces coupled with the one or more antennas 1015 that are configured to support various transmitting or outputting operations, or a combination thereof. In some implementations, the transceiver 1010 may include or be configured for coupling with one or more processors or one or more memory components that are operable to perform or support operations based on received or obtained information or signals, or to generate information or other signals for transmission or other outputting, or any combination thereof. In some implementations, the transceiver 1010, or the transceiver 1010 and the one or more antennas 1015, or the transceiver 1010 and the one or more antennas 1015 and one or more processors or one or more memory components (e.g., the at least one processor 1035, the at least one memory 1025, or both), may be included in a chip or chip assembly that is installed in the device 1005. In some examples, the transceiver 1010 may be operable to support communications via one or more communications links (e.g., communication link(s) 125, backhaul communication link(s) 120, a midhaul communication link 162, a fronthaul communication link 168).

The at least one memory 1025 may include RAM, ROM, or any combination thereof. The at least one memory 1025 may store computer-readable, computer-executable, or processor-executable code, such as the code 1030. The code 1030 may include instructions that, when executed by one or more of the at least one processor 1035, cause the device 1005 to perform various functions described herein. The code 1030 may be stored in a non-transitory computer-readable medium such as system memory or another type of memory. In some cases, the code 1030 may not be directly executable by a processor of the at least one processor 1035 but may cause a computer (e.g., when compiled and executed) to perform functions described herein. In some cases, the at least one memory 1025 may include, among other things, a BIOS which may control basic hardware or software operation such as the interaction with peripheral components or devices. In some examples, the at least one processor 1035 may include multiple processors and the at least one memory 1025 may include multiple memories. One or more of the multiple processors may be coupled with one or more of the multiple memories which may, individually or collectively, be configured to perform various functions herein (for example, as part of a processing system).

The at least one processor 1035 may include one or more intelligent hardware devices (e.g., one or more general-purpose processors, one or more DSPs, one or more CPUs, one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 1035 may be configured to operate a memory array using a memory controller. In some other cases, a memory controller may be integrated into one or more of the at least one processor 1035. The at least one processor 1035 may be configured to execute computer-readable instructions stored in a memory (e.g., one or more of the at least one memory 1025) to cause the device 1005 to perform various functions (e.g., functions or tasks supporting low density parity check techniques in wireless communications). For example, the device 1005 or a component of the device 1005 may include at least one processor 1035 and at least one memory 1025 coupled with one or more of the at least one processor 1035, the at least one processor 1035 and the at least one memory 1025 configured to perform various functions described herein. The at least one processor 1035 may be an example of a cloud-computing platform (e.g., one or more physical nodes and supporting software such as operating systems, virtual machines, or container instances) that may host the functions (e.g., by executing code 1030) to perform the functions of the device 1005. The at least one processor 1035 may be any one or more suitable processors capable of executing scripts or instructions of one or more software programs stored in the device 1005 (such as within one or more of the at least one memory 1025).

In some examples, the at least one processor 1035 may include multiple processors and the at least one memory 1025 may include multiple memories. One or more of the multiple processors may be coupled with one or more of the multiple memories, which may, individually or collectively, be configured to perform various functions herein. In some examples, the at least one processor 1035 may be a component of a processing system, which may refer to a system (such as a series) of machines, circuitry (including, for example, one or both of processor circuitry (which may include the at least one processor 1035) and memory circuitry (which may include the at least one memory 1025)), or components, that receives or obtains inputs and processes the inputs to produce, generate, or obtain a set of outputs. The processing system may be configured to perform one or more of the functions described herein. For example, the at least one processor 1035 or a processing system including the at least one processor 1035 may be configured to, configurable to, or operable to cause the device 1005 to perform one or more of the functions described herein. Further, as described herein, being “configured to,” being “configurable to,” and being “operable to” may be used interchangeably and may be associated with a capability, when executing code stored in the at least one memory 1025 or otherwise, to perform one or more of the functions described herein.

In some examples, a bus 1040 may support communications of (e.g., within) a protocol layer of a protocol stack. In some examples, a bus 1040 may support communications associated with a logical channel of a protocol stack (e.g., between protocol layers of a protocol stack), which may include communications performed within a component of the device 1005, or between different components of the device 1005 that may be co-located or located in different locations (e.g., where the device 1005 may refer to a system in which one or more of the communications manager 1020, the transceiver 1010, the at least one memory 1025, the code 1030, and the at least one processor 1035 may be located in one of the different components or divided between different components).

In some examples, the communications manager 1020 may manage aspects of communications with a core network 130 (e.g., via one or more wired or wireless backhaul links). For example, the communications manager 1020 may manage the transfer of data communications for client devices, such as one or more UEs 115. In some examples, the communications manager 1020 may manage communications with one or more other network entities 105, and may include a controller or scheduler for controlling communications with UEs 115 (e.g., in cooperation with the one or more other network devices). In some examples, the communications manager 1020 may support an X2 interface within an LTE/LTE-A wireless communications network technology to provide communication between network entities 105.

The communications manager 1020 may support wireless communications in accordance with examples as disclosed herein. For example, the communications manager 1020 is capable of, configured to, or operable to support a means for obtaining a set of information bits to be transmitted from the wireless device. The communications manager 1020 is capable of, configured to, or operable to support a means for generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The communications manager 1020 is capable of, configured to, or operable to support a means for transmitting a codeword based on the set of information bits and the parity check matrix.

Additionally, or alternatively, the communications manager 1020 may support wireless communications in accordance with examples as disclosed herein. For example, the communications manager 1020 is capable of, configured to, or operable to support a means for obtaining a set of information bits to be transmitted from the wireless device. The communications manager 1020 is capable of, configured to, or operable to support a means for generating a parity check matrix based on the set of information bits, the parity check matrix including a base graph matrix and a lifted matrix. The communications manager 1020 is capable of, configured to, or operable to support a means for generating a codeword for transmission that includes systematic bits that correspond to the set of information bits and parity bits that are generated from the parity check matrix. The communications manager 1020 is capable of, configured to, or operable to support a means for mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. The communications manager 1020 is capable of, configured to, or operable to support a means for transmitting the codeword to a receiving device.

By including or configuring the communications manager 1020 in accordance with examples as described herein, the device 1005 may support techniques for faster convergence for decoding LDPC codes, which may provide for efficient processing using less processing resources per decoding of CBs.

In some examples, the communications manager 1020 may be configured to perform various operations (e.g., receiving, obtaining, monitoring, outputting, transmitting) using or otherwise in cooperation with the transceiver 1010, the one or more antennas 1015 (e.g., where applicable), or any combination thereof. Although the communications manager 1020 is illustrated as a separate component, in some examples, one or more functions described with reference to the communications manager 1020 may be supported by or performed by the transceiver 1010, one or more of the at least one processor 1035, one or more of the at least one memory 1025, the code 1030, or any combination thereof (for example, by a processing system including at least a portion of the at least one processor 1035, the at least one memory 1025, the code 1030, or any combination thereof). For example, the code 1030 may include instructions executable by one or more of the at least one processor 1035 to cause the device 1005 to perform various aspects of low density parity check techniques in wireless communications as described herein, or the at least one processor 1035 and the at least one memory 1025 may be otherwise configured to, individually or collectively, perform or support such operations.

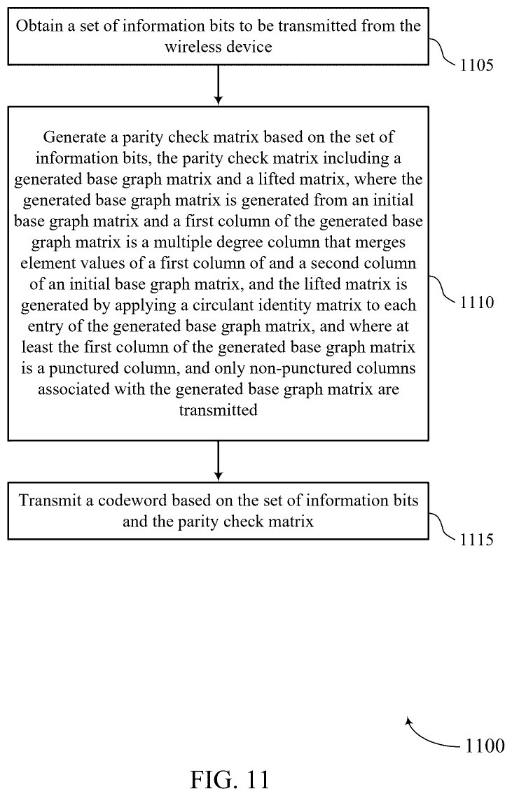

FIG. 11 shows a flowchart illustrating a method 1100 that supports low density parity check techniques in wireless communications in accordance with one or more aspects of the present disclosure. The operations of the method 1100 may be implemented by a UE or a network entity or its components as described herein. For example, the operations of the method 1100 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1105, the method may include obtaining a set of information bits to be transmitted from the wireless device. The operations of 1105 may be performed in accordance with examples as disclosed herein. In some examples, aspects of the operations of 1105 may be performed by a transmit buffer component 825 as described with reference to FIG. 8.

At 1110, the method may include generating a parity check matrix based on the set of information bits, the parity check matrix including a generated base graph matrix and a lifted matrix, where the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and where at least the first column of the generated base graph matrix is a punctured column, and only non-punctured columns associated with the generated base graph matrix are transmitted. The operations of 1110 may be performed in accordance with examples as disclosed herein. In some examples, aspects of the operations of 1110 may be performed by a parity generation component 830 as described with reference to FIG. 8.

At 1115, the method may include transmitting a codeword based on the set of information bits and the parity check matrix. The operations of 1115 may be performed in accordance with examples as disclosed herein. In some examples, aspects of the operations of 1115 may be performed by a modulation component 835 as described with reference to FIG. 8.

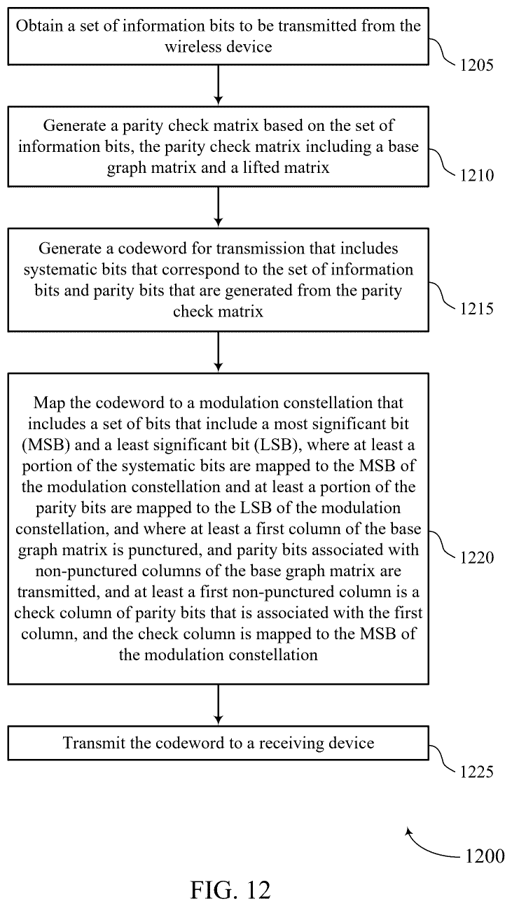

FIG. 12 shows a flowchart illustrating a method 1200 that supports low density parity check techniques in wireless communications in accordance with one or more aspects of the present disclosure. The operations of the method 1200 may be implemented by a UE or a network entity or its components as described herein. For example, the operations of the method 1200 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1205, the method may include obtaining a set of information bits to be transmitted from the wireless device. The operations of 1205 may be performed in accordance with examples as disclosed herein. In some examples, aspects of the operations of 1205 may be performed by a transmit buffer component 825 as described with reference to FIG. 8.

At 1210, the method may include generating a parity check matrix based on the set of information bits, the parity check matrix including a base graph matrix and a lifted matrix. The operations of 1210 may be performed in accordance with examples as disclosed herein. In some examples, aspects of the operations of 1210 may be performed by a parity generation component 830 as described with reference to FIG. 8.

At 1215, the method may include generating a codeword for transmission that includes systematic bits that correspond to the set of information bits and parity bits that are generated from the parity check matrix. The operations of 1215 may be performed in accordance with examples as disclosed herein. In some examples, aspects of the operations of 1215 may be performed by a modulation component 835 as described with reference to FIG. 8.

At 1220, the method may include mapping the codeword to a modulation constellation that includes a set of bits that include a most significant bit (MSB) and a least significant bit (LSB), where at least a portion of the systematic bits are mapped to the MSB of the modulation constellation and at least a portion of the parity bits are mapped to the LSB of the modulation constellation, and where at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation. The operations of 1220 may be performed in accordance with examples as disclosed herein. In some examples, aspects of the operations of 1220 may be performed by a modulation component 835 as described with reference to FIG. 8.

At 1225, the method may include transmitting the codeword to a receiving device. The operations of 1225 may be performed in accordance with examples as disclosed herein. In some examples, aspects of the operations of 1225 may be performed by a modulation component 835 as described with reference to FIG. 8.

The following provides an overview of aspects of the present disclosure:

Aspect 1: A method for wireless communications at a wireless device, comprising: obtaining a set of information bits to be transmitted from the wireless device; generating a parity check matrix based at least in part on the set of information bits, the parity check matrix comprising a generated base graph matrix and a lifted matrix, wherein the generated base graph matrix is generated from an initial base graph matrix and a first column of the generated base graph matrix is a multiple degree column that merges element values of a first column of and a second column of an initial base graph matrix, and the lifted matrix is generated by applying a circulant identity matrix to each entry of the generated base graph matrix, and wherein at least the first column of the generated base graph matrix is a punctured column, and only non-punctured columns associated with the generated base graph matrix are transmitted; and transmitting a codeword based at least in part on the set of information bits and the parity check matrix.

Aspect 2: The method of aspect 1, wherein the first column of the generated base graph matrix merges a degree of each corresponding element of the first column of the initial base graph matrix and the second column of the initial base graph matrix, and both the first column of the initial base graph matrix and the second column of the initial base graph matrix are punctured columns.

Aspect 3: The method of any of aspects 1 through 2, wherein the circulant identity matrix is a Z by Z identity matrix that is shifted in accordance with a cyclic shift value of a corresponding element of the generated base graph matrix, and wherein values of cyclic shifts associated with double edges in the first column of the generated base graph matrix are selected such that the cyclic shift values are not equal under modulo Z for each available value of Z.

Aspect 4: The method of aspect 1, wherein the first column of the generated base graph matrix merges a degree of each corresponding element of the first column of the initial base graph matrix and the second column of the initial base graph matrix, the first column of the generated base graph matrix is a punctured column and the second column of the generated base graph matrix is an unpunctured column that corresponds to the second column of the initial base graph matrix or is a generated column that is based at least in part on elements of the first column of the initial base graph matrix and the second column of the initial base graph matrix, and remaining columns of the generated base graph matrix other than the first column and the second column are unpunctured columns.

Aspect 5: The method of any of aspects 1 through 4, wherein the circulant identity matrix is a Z by Z identity matrix that is shifted in accordance with a cyclic shift value of a corresponding element of the generated base graph matrix, and wherein available values for Z are selected based at least in part on a quantity of edges of the generated base graph matrix, wherein an edge of the generated base graph matrix corresponds to an element of the generated base graph matrix that has an adjacent non-zero element of the generated base graph matrix.

Aspect 6: The method of any of aspects 1 through 5, wherein a dimension of the circulant identity matrix is Z×Z, and wherein a total size of the parity check matrix is a size of the generated base graph matrix multiplied by Z.

Aspect 7: A method for wireless communications at a wireless device, comprising: obtaining a set of information bits to be transmitted from the wireless device; generating a parity check matrix based at least in part on the set of information bits, the parity check matrix comprising a base graph matrix and a lifted matrix; generating a codeword for transmission that includes systematic bits that correspond to the set of information bits and parity bits that are generated from the parity check matrix; mapping the codeword to a modulation constellation that comprises a set of bits that include a most significant bit (MSB) and a least significant bit (LSB), wherein at least a portion of the systematic bits are mapped to the MSB of the modulation constellation and at least a portion of the parity bits are mapped to the LSB of the modulation constellation, and wherein at least a first column of the base graph matrix is punctured, and parity bits associated with non-punctured columns of the base graph matrix are transmitted, and at least a first non-punctured column is a check column of parity bits that is associated with the first column, and the check column is mapped to the MSB of the modulation constellation; and transmitting the codeword to a receiving device.

Aspect 8: The method of aspect 7, wherein the check column is a last column of the base graph matrix, and the codeword is mapped to the modulation constellation such that the check column and one or more initial columns of the base graph matrix that correspond to the systematic bits are mapped to the MSB of the modulation constellation.

Aspect 9: The method of aspect 7, wherein the check column is moved to an initial column of the base graph matrix, and the codeword is mapped to the modulation constellation in accordance with an order of the non-punctured columns of the base graph matrix.

Aspect 10: The method of any of aspects 7 through 9, wherein copies of transmitted bits associated with each column of the base graph matrix have a corresponding channel reliability in accordance with the mapping of the codeword to the modulation constellation, and transmitted bits associated with different columns of the base graph matrix may have different channel reliabilities in accordance with the mapping of the codeword to the modulation constellation.

Aspect 11: A wireless device for wireless communications, comprising one or more memories storing processor-executable code, and one or more processors coupled with the one or more memories and individually or collectively operable to execute the code to cause the wireless device to perform a method of any of aspects 1 through 6.

Aspect 12: A wireless device for wireless communications, comprising at least one means for performing a method of any of aspects 1 through 6.

Aspect 13: A non-transitory computer-readable medium storing code for wireless communications, the code comprising instructions executable by one or more processors to perform a method of any of aspects 1 through 6.

Aspect 14: A wireless device for wireless communications, comprising one or more memories storing processor-executable code, and one or more processors coupled with the one or more memories and individually or collectively operable to execute the code to cause the wireless device to perform a method of any of aspects 7 through 10.

Aspect 15: A wireless device for wireless communications, comprising at least one means for performing a method of any of aspects 7 through 10.

Aspect 16: A non-transitory computer-readable medium storing code for wireless communications, the code comprising instructions executable by one or more processors to perform a method of any of aspects 7 through 10.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A wireless device, comprising:
one or more memories storing processor-executable code; and
one or more processors coupled with the one or more memories and individually or collectively operable to execute the code to cause the wireless device to:
obtain a set of information bits to be transmitted from the wireless device;
generate a parity check matrix based at least in part on the set of information bits, the parity check matrix comprising a generated base graph matrix and a lifted matrix, wherein the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and wherein at least the first column of the generated base graph matrix is a punctured column, and only non-punctured columns associated with the generated base graph matrix are transmitted; and
transmit a codeword based at least in part on the set of information bits and the parity check matrix.

2. The wireless device of claim 1, wherein the first column of the generated base graph matrix merges a degree of each corresponding element of the first column of the initial base graph matrix and the second column of the initial base graph matrix, and both the first column of the initial base graph matrix and the second column of the initial base graph matrix are punctured columns.

3. The wireless device of claim 1, wherein the circulant identity matrix is a Z by Z identity matrix that is shifted in accordance with a cyclic shift value of a corresponding element of the generated base graph matrix, and wherein values of cyclic shifts associated with double edges in the first column of the generated base graph matrix are selected such that the cyclic shift values are not equal under modulo Z for each available value of Z.

4. The wireless device of claim 1, wherein:
the first column of the generated base graph matrix merges a degree of each corresponding element of the first column of the initial base graph matrix and the second column of the initial base graph matrix,
the first column of the generated base graph matrix is a punctured column and the second column of the generated base graph matrix is an unpunctured column that corresponds to the second column of the initial base graph matrix or is a generated column that is based at least in part on elements of the first column of the initial base graph matrix and the second column of the initial base graph matrix, and
remaining columns of the generated base graph matrix other than the first column and the second column are unpunctured columns.

5. The wireless device of claim 1, wherein the circulant identity matrix is a Z by Z identity matrix that is shifted in accordance with a cyclic shift value of a corresponding element of the generated base graph matrix, and wherein available values for Z are selected based at least in part on a quantity of edges of the generated base graph matrix, wherein an edge of the generated base graph matrix corresponds to an element of the generated base graph matrix that has an adjacent non-zero element of the generated base graph matrix.

6. The wireless device of claim 1, wherein a dimension of the circulant identity matrix is Z×Z, and wherein a total size of the parity check matrix is a size of the generated base graph matrix multiplied by Z.

7. The wireless device of claim 1, wherein the one or more processors are individually or collectively operable to execute the code to cause the wireless device:
transmit a capability indication to a receiving wireless device that indicates the wireless device is capable of generating the generated base graph matrix with the multiple degree column; and
receive signaling that indicates to use the generated base graph matrix with the multiple degree first column.

8. The wireless device of claim 7, wherein the capability indication and the signaling are exchanged via radio resource control (RRC) signaling, a medium access control (MAC) control element, a downlink control information (DCI) transmission, or any combination thereof.

9. A wireless device, comprising:
one or more memories storing processor-executable code; and
one or more processors coupled with the one or more memories and individually or collectively operable to execute the code to cause the wireless device to:
obtain a set of information bits to be transmitted from the wireless device;
generate a parity check matrix based at least in part on the set of information bits, the parity check matrix comprising a base graph matrix and a lifted matrix;
generate a codeword for transmission that includes systematic bits that correspond to the set of information bits and parity bits that are generated from the parity check matrix;
map the codeword to a modulation constellation that comprises a set of bits that include a most significant bit (MSB) and a least significant bit (LSB), wherein:
at least a portion of the systematic bits are mapped to the MSB of the modulation constellation and at least a portion of the parity bits are mapped to the LSB of the modulation constellation,
at least a first column of the base graph matrix is punctured, and parity bits associated with non-punctured columns of the base graph matrix are transmitted, and at least a first non-punctured column is a check column of parity bits that is associated with the first column, and
the check column is mapped to the MSB of the modulation constellation; and
transmit the codeword to a receiving device.

10. The wireless device of claim 9, wherein the check column is a last column of the base graph matrix, and the codeword is mapped to the modulation constellation such that the check column and one or more initial columns of the base graph matrix that correspond to the systematic bits are mapped to the MSB of the modulation constellation.

11. The wireless device of claim 9, wherein the check column is moved to an initial column of the base graph matrix, and the codeword is mapped to the modulation constellation in accordance with an order of the non-punctured columns of the base graph matrix.

12. The wireless device of claim 9, wherein copies of transmitted bits associated with each column of the base graph matrix have a corresponding channel reliability in accordance with the mapping of the codeword to the modulation constellation, and transmitted bits associated with different columns of the base graph matrix may have different channel reliabilities in accordance with the mapping of the codeword to the modulation constellation.

13. A method for wireless communications at a wireless device, comprising:
obtaining a set of information bits to be transmitted from the wireless device;
generating a parity check matrix based at least in part on the set of information bits, the parity check matrix comprising a generated base graph matrix and a lifted matrix, wherein the generated base graph matrix is generated from an initial base graph matrix and a first column of the generated base graph matrix is a multiple degree column that merges element values of a first column and a second column of an initial base graph matrix, and the lifted matrix is generated by applying a circulant identity matrix to each entry of the generated base graph matrix, and wherein at least the first column of the generated base graph matrix is a punctured column, and only non-punctured columns associated with the generated base graph matrix are transmitted; and
transmitting a codeword based at least in part on the set of information bits and the parity check matrix.

14. The method of claim 13, wherein the first column of the generated base graph matrix merges a degree of each corresponding element of the first column of the initial base graph matrix and the second column of the initial base graph matrix, and both the first column of the initial base graph matrix and the second column of the initial base graph matrix are punctured columns.

15. The method of claim 13, wherein the circulant identity matrix is a Z by Z identity matrix that is shifted in accordance with a cyclic shift value of a corresponding element of the generated base graph matrix, and wherein values of cyclic shifts associated with double edges in the first column of the generated base graph matrix are selected such that the cyclic shift values are not equal under modulo Z for each available value of Z.

16. The method of claim 13, wherein:
the first column of the generated base graph matrix merges a degree of each corresponding element of the first column of the initial base graph matrix and the second column of the initial base graph matrix,
the first column of the generated base graph matrix is a punctured column and the second column of the generated base graph matrix is an unpunctured column that corresponds to the second column of the initial base graph matrix or is a generated column that is based at least in part on elements of the first column of the initial base graph matrix and the second column of the initial base graph matrix, and
remaining columns of the generated base graph matrix other than the first column and the second column are unpunctured columns.

17. The method of claim 13, wherein the circulant identity matrix is a Z by Z identity matrix that is shifted in accordance with a cyclic shift value of a corresponding element of the generated base graph matrix, and wherein available values for Z are selected based at least in part on a quantity of edges of the generated base graph matrix, wherein an edge of the generated base graph matrix corresponds to an element of the generated base graph matrix that has an adjacent non-zero element of the generated base graph matrix.

18. The method of claim 13, wherein a dimension of the circulant identity matrix is Z×Z, and wherein a total size of the parity check matrix is a size of the generated base graph matrix multiplied by Z.

19. The wireless device of claim 13, further comprising:
transmitting a capability indication to a receiving wireless device that indicates the wireless device is capable of generating the generated base graph matrix with the multiple degree column; and
receiving signaling that indicates to use the generated base graph matrix with the multiple degree first column.

20. The wireless device of claim 19, wherein the capability indication and the signaling are exchanged via radio resource control (RRC) signaling, a medium access control (MAC) control element, a downlink control information (DCI) transmission, or any combination thereof.
